(19) United States
(12) Patent Application Publication
(10) Pub. No.: US 2022/0115545 A1
(43) Pub. Date: Apr. 14, 2022

(54) TUNNEL OXIDE PASSIVATED CONTACT SOLAR CELL

(71) Applicant: United Renewable Energy Co., Ltd., Hsinchu City (TW)

(72) Inventors: Chih-Jeng HUANG, HSINCHU CITY (TW); Jen-Hao SONG, HSINCHU CITY (TW); An-Chih HSUEH, HSINCHU CITY (TW)

(73) Assignee: United Renewable Energy Co., Ltd., HSINCHU CITY (TW)

(21) Appl. No.: 17/156,980

(22) Filed: Jan. 25, 2021

(30) Foreign Application Priority Data
Oct. 8, 2020 (TW) 109213266

(51) Int. Cl. H01L 31/0216; H01L 31/0224; H01L 31/0236; H01L 31/068

(52) U.S. Cl. CPC H01L 31/02167; H01L 31/02168; H01L 31/0682; H01L 31/02363; H01L 31/022466

(57) ABSTRACT

A tunnel oxide passivated contact solar cell includes a semiconductor substrate, an emitter film layer, an anti-reflective layer, a first electrode, a tunnel oxide layer, a semiconductor film layer and a second electrode. The semiconductor substrate is a first type doped semiconductor, and the first surface of the semiconductor substrate includes a zigzag structure. The emitter film layer is a second type doped semiconductor film. The anti-reflective layer is provided with a first opening. A part of the first electrode is in the first opening and electrically connected to the emitter film layer. The tunnel oxide layer has a thickness ranging from 1.3 nm to 1.6 nm, the thickness difference measured is less than 4%, and the tunnel oxide layer is made by an atomic layer deposition process. The semiconductor film layer is a first type doped semiconductor. The second electrode is electrically connected to the semiconductor film layer.

### CROSS-REFERENCE TO RELATED APPLICATION

This non-provisional application claims priority under 35 U.S.C. § 119(a) to Patent Application No. 109213266 filed in Taiwan, R.O.C. on Oct. 8, 2020, the entire contents of which are hereby incorporated by reference.

### BACKGROUND

### Technical Field

This creation relates to the field of solar energy, and in particular relates to a tunnel oxide passivated contact (TOPCon) solar cell.

### Related Art

With the development of the green energy industry, the conversion efficiency of solar cells has been effectively improved. Tunnel oxide passivated contact solar cells and Heterojunction Technology (HJT) solar cells are considered as a type of solar cell with mainstream potential and high conversion efficiency.

The tunnel oxide passivated contact solar cell is characterized by having an extremely thin tunnel oxide layer. The existing problem is that the thickness of the tunnel oxide layer cannot be controlled stably, and the difference in uniformity, that is, the difference in thickness generally measured by points may be as high as 15%. In addition, the production yield is still not high.

### SUMMARY

Here, a tunnel oxide passivated contact solar cell is provided. The tunnel oxide passivated contact solar cell includes a semiconductor substrate, an emitter film layer, an anti-reflective layer, a first electrode, a tunnel oxide layer, a semiconductor film layer and a second electrode.

The semiconductor substrate is a first type doped semiconductor and includes a first surface and a second surface, the first surface includes a zigzag structure, and the second surface is on the opposite surface of the first surface. The emitter film layer is a second type doped semiconductor film, is disposed on the first surface, and has a thickness ranging from 50 nm to 80 nm. The anti-reflective layer is disposed on the emitter film layer, has a thickness ranging from 5 nm to 40 nm, and is provided with a first opening penetrating through the anti-reflective layer. A part of the first electrode is disposed in the first opening and is electrically connected to the emitter film layer. The tunnel oxide layer is disposed on the second surface and has a thickness ranging from 1.3 nm to 1.6 nm, the thickness difference measured by five points measurement thereon is less than 4%, and the tunnel oxide layer is made by an atomic layer deposition (ALD) process. The semiconductor film layer is a first type doped semiconductor, is disposed on the tunnel oxide layer, and has a thickness ranging from 100 nm to 150 nm. The second electrode is disposed on the semiconductor film layer and is electrically connected to the semiconductor film layer.

In some embodiments, the tunnel oxide passivated contact solar cell further includes a first protective layer. The first protective layer is disposed on the anti-reflective layer and is provided with a through hole. The through hole is communicated with the first opening, and a part of the first electrode is disposed in the first opening and the through hole and is electrically connected to the emitter film layer.

In more detail, in some embodiments, the tunnel oxide passivated contact solar cell further includes a second protective layer, the second protective layer is disposed on the semiconductor film layer and is provided with a second opening penetrating through the second protective layer, and a part of the second electrode is disposed in the second opening and is in contact with the semiconductor film layer.

In more detail, in some embodiments, a second tunnel oxide layer is further disposed between the emitter film layer and the first surface and has a thickness ranging from 1.3 nm to 1.6 nm, the thickness difference measured by five points measurement thereon is less than 4%, and the second tunnel oxide layer is made by an atomic layer deposition process.

In more detail, in some embodiments, a transparent conductive layer is further disposed between the emitter film layer and the anti-reflective layer, and the thickness of the transparent conductive layer ranges from 40 nm to 80 nm.

In more detail, in some embodiments, the first electrode is disposed in the first opening and is in contact with the transparent conductive layer.

In more detail, in some embodiments, a second transparent conductive layer is further disposed on the semiconductor film layer, the thickness of the second transparent conductive layer ranges from 50 nm to 80 nm, and the second electrode is in contact with the second transparent conductive layer.

In some embodiments, the thickness of the semiconductor substrate ranges from 90 um to 160 um.

In some embodiments, the first type doped semiconductor is an N type doped semiconductor, and the second type doped semiconductor is a P type doped semiconductor.

In some other embodiments, the first type doped semiconductor is a P type doped semiconductor, and the second type doped semiconductor is an N type doped semiconductor.

In conclusion, the tunnel oxide layer is made by the atomic layer deposition process to effectively control the thickness to be from 1.3 nm to 1.6 nm, that is, less than the difference in height between two atoms, so that the uniformity is greatly improved, the stability of an open circuit voltage and the conversion efficiency of the tunnel oxide passivated contact solar cell can be improved, and the process yield can be further effectively improved to 95% or more.

### BRIEF DESCRIPTION OF THE DRAWINGS

FIG. 1 is a schematic cross-sectional diagram of a tunnel oxide passivated contact solar cell according to a first embodiment.

FIG. 2 is a schematic cross-sectional diagram of a tunnel oxide passivated contact solar cell according to a second embodiment.

FIG. 3 is a schematic cross-sectional diagram of a tunnel oxide passivated contact solar cell according to a third embodiment.

FIG. 4 is a schematic cross-sectional diagram of a tunnel oxide passivated contact solar cell according to a fourth embodiment.

### DETAILED DESCRIPTION

It should be understood that when an element is referred to as being “connected” or “disposed” to another element, it can mean that the element is directly located on another element, or there may also be an intermediate element through which the element is connected to another element. On the contrary, when an element is referred to as being “directly located on another element” or “directly connected to another element”, it can be understood that at this time, it is clearly defined that there is no intermediate element.

In addition, the terms “first”, “second” and “third” are only used to distinguish one element, component, region or part from another element, component, region, layer or part, rather than indicating its inevitable sequence. Furthermore, relative terms such as “lower” and “upper” may be used herein to describe the relationship between one element and another element. It should be understood that the relative terms are intended to include different orientations of the device other than those shown in the figures. For example, if the device in one figure is turned over, elements described as being on the “lower” side of other elements will be oriented on the “upper” side of the other elements. This only represents a relative orientation relationship, not an absolute orientation relationship.

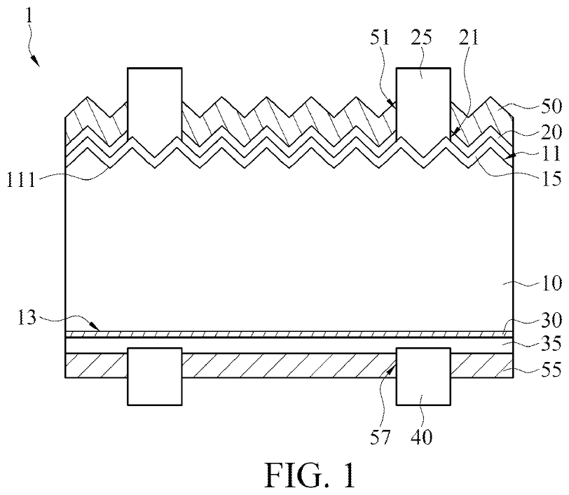

FIG. 1 is a schematic cross-sectional diagram of a tunnel oxide passivated contact solar cell according to a first embodiment. As shown in FIG. 1, a tunnel oxide passivated contact solar cell 1 includes a semiconductor substrate 10, an emitter film layer 15, an anti-reflective layer 20, a first electrode 25, a tunnel oxide layer 30, a semiconductor film layer 35 and a second electrode 40.

The semiconductor substrate 10 is a first type doped semiconductor, such as an N type silicon substrate or a P type silicon substrate. The semiconductor substrate 10 includes a first surface 11 and a second surface 13, the first surface 11 includes a zigzag structure 111, and the second surface 13 is on the opposite surface of the first surface 11. The zigzag structure 111 increases the probability of photons entering the emitter film layer 15, and increases the efficiency of photoelectric conversion. In some embodiments, the thickness of the semiconductor substrate 10 ranges from 90 um to 160 um, preferably 110 um to 150 um.

The emitter film layer 15 is a second type doped semiconductor film. In general, both the emitter film layer and the semiconductor substrate 10 are silicon, and can adopt polycrystalline silicon. Here, the second type doping is relative to the first type doping. In other words, when the first type doping is N type, the second type doping is P type, and when the first type doping is P type, the second type doping is N type. The emitter film layer 15 is disposed on the first surface 11 and fluctuates with the zigzag structure 111, and the thickness of the emitter film layer 15 ranges from 50 nm to 80 nm, preferably from 60 nm to 75 nm.

The anti-reflective layer 20 is disposed on the emitter film layer 15, has a thickness ranging from 5 nm to 40 nm, preferably 10 nm to 30 nm, and is provided with a first opening 21 penetrating through the anti-reflective layer 20. The anti-reflective layer 20 is usually an aluminum oxide film, and in addition to an anti-reflective effect, the anti-reflective layer also has a passivation effect. A part of the first electrode 25 is disposed in the first opening 21 and is electrically connected to the emitter film layer 15. In the present embodiment, the first electrode 25 is made of silver paste, which fills the first opening 21 and is in direct contact with the emitter film layer 15, and a part of the first electrode 25 protrudes outside the first opening 21 to form a contact finger.

The tunnel oxide layer 30 is disposed on the second surface 13, is usually silicon oxide (SiOₓ), and has a thickness ranging from 1.3 nm to 1.6 nm, and preferably 1.5 nm. In other words, the difference in thickness range is less than the height of two atoms, and the uniformity thereon, that is, the thickness difference measured by five points measurement is less than 4%. The tunnel oxide layer 30 is made by an atomic layer deposition (ALD) process. In general, both the semiconductor film layer 35 and the semiconductor substrate 10 are silicon, and can adopt polycrystalline silicon. The semiconductor film layer 35 is a first type doped semiconductor, is disposed on the tunnel oxide layer 30, and has a thickness ranging from 100 nm to 150 nm. The second electrode 40 is disposed on the semiconductor film layer 35 and is electrically connected to the semiconductor film layer 35. In the present embodiment, the second electrode 40 is also made of silver paste and is in contact with the semiconductor film layer 35.

Referring to FIG. 1 again, in some embodiments, the tunnel oxide passivated contact solar cell 1 further includes a first protective layer 50. The first protective layer 50 is disposed on the anti-reflective layer 20 and is provided with a through hole 51, the through hole 51 is communicated with the first opening 21, and a part of the first electrode 25 is disposed in the first opening 21 and the through hole 51 and is in contact with the emitter film layer 15 so as to be electrically connected. In addition, in some embodiments, the tunnel oxide passivated contact solar cell 1 further includes a second protective layer 55, the second protective layer 55 is disposed on the semiconductor film layer 35 and is provided with a second opening 57 penetrating through the second protective layer 55, and a part of the second electrode 40 is disposed in the second opening 57 and is in contact with the semiconductor film layer 35 so as to be electrically connected. Here, the first protective layer 50 and the second protective layer 55 may be silicon nitride (SiNₓ), which cannot only provide protection, but also enhance the anti-reflective effect. The thickness of the first protective layer 50 ranges from 20 nm to 80 nm, preferably 30 nm to 70 nm, and the thickness of the second protective layer 55 ranges from 40 nm to 100 nm, preferably 50 nm to 90 nm.

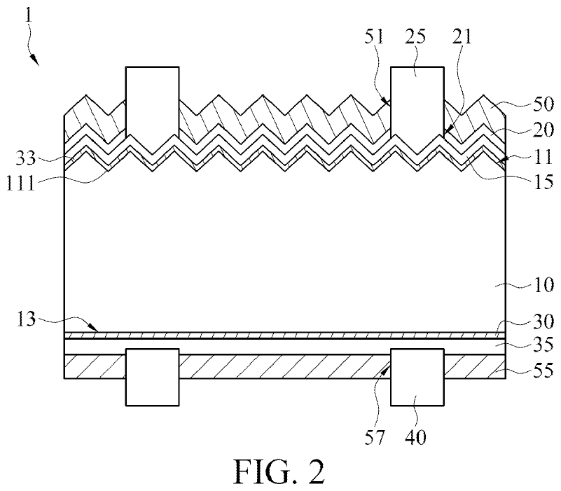

FIG. 2 is a schematic cross-sectional diagram of a tunnel oxide passivated contact solar cell according to a second embodiment. As shown in FIG. 2 and referring to FIG. 1, the second embodiment further includes a second tunnel oxide layer 33 between the emitter film layer 15 and the first surface 11, and the second tunnel oxide layer 33 also fluctuates with the zigzag structure 111. The second tunnel oxide layer 33 has a thickness ranging from 1.3 nm to 1.6 nm, preferably 1.5 nm, and the thickness difference measured by five points measurement thereon is less than 4%. The second tunnel oxide layer 33 is made by an atomic layer deposition process. In this way, the second embodiment forms a structure with tunnel oxide layers (30, 33) on both sides.

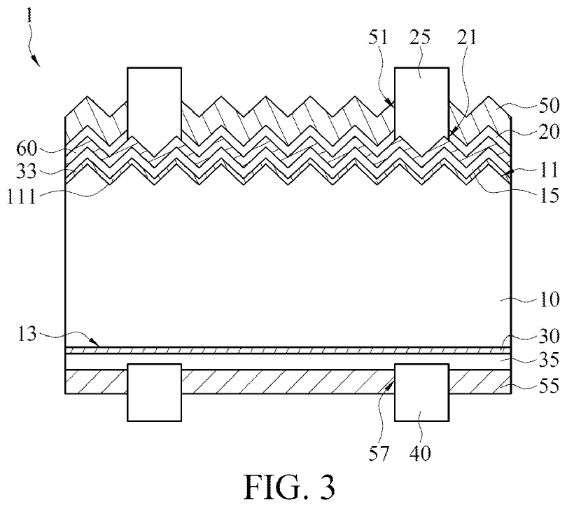

FIG. 3 is a schematic cross-sectional diagram of a tunnel oxide passivated contact solar cell according to a third embodiment. As shown in FIG. 3 and referring to FIG. 2, a transparent conductive layer 60 is further disposed between the emitter film layer 15 and the anti-reflective layer 20, and the thickness of the transparent conductive layer 60 ranges from 40 nm to 80 nm, preferably from 50 nm to 60 nm. At this time, the first electrode 25 is disposed in the first opening 21, is in contact with the transparent conductive layer 60, and is not in direct contact with the emitter film layer 15. Through the transparent conductive layer 60, the self-absorption phenomenon of electron hole pairs in the emitter film layer 15 can be reduced. Furthermore, through the transparent conductive layer 60, the emitter film layer 15 can be made thinner, so that the light transmission of the emitter film layer 15 is increased so as to further reduce the degree of incident light absorption by the emitter film layer 15.

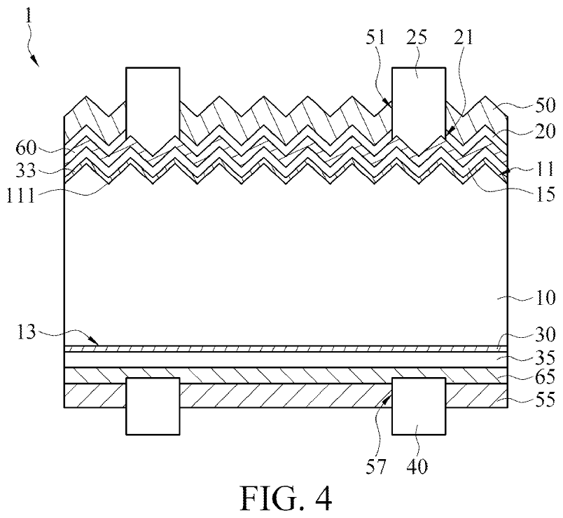

FIG. 4 is a schematic cross-sectional diagram of a tunnel oxide passivated contact solar cell according to a fourth embodiment. As shown in FIG. 4 and referring to FIG. 3, a second transparent conductive layer 65 is further disposed on the semiconductor film layer 35, and the thickness of the second transparent conductive layer 65 ranges from 40 nm to 80 nm, preferably 50 nm to 60 nm. The second electrode 40 is in contact with the second transparent conductive layer 65 and is not in direct contact with the semiconductor film layer 35. The above is only an example, and not a limitation. For example, the tunnel oxide passivated contact solar cell 1 can also be only provided with the second transparent conductive layer 65 of the semiconductor film layer 35.

In conclusion, the tunnel oxide layer 30 is made by the atomic layer deposition process in this creation to effectively control the thickness to be from 1.3 nm to 1.6 nm, that is, the difference in thickness is less than the difference in height between two atoms, so that the uniformity is greatly improved, the stability of an open circuit voltage and the conversion efficiency of the tunnel oxide passivated contact solar cell 1 can be improved, and the process yield can be further effectively improved to 95% or more.

Through the above detailed description, it can be fully demonstrated that the objectives and effects of this creation are progressive in implementation, and this creation has great industrial utility value and fully meets the requirements of the patent, so an application is filed in accordance with the law. The above embodiments are only preferred embodiments of this creation, and should not be used to limit the scope of implementation of this creation. All equivalent changes and modifications made in accordance with the range of this patent shall fall within the scope of this patent. I would like to ask your review members to give correct judgment, and pray for the permission.

What is claimed is:

1. A tunnel oxide passivated contact solar cell, comprising:
a semiconductor substrate being a first type doped semiconductor and comprising a first surface and a second surface, wherein the first surface comprises a zigzag structure, and the second surface is on the opposite surface of the first surface;
an emitter film layer being a second type doped semiconductor film, on the first surface, and having a thickness ranging from 50 nm to 80 nm;
an anti-reflective layer on the emitter film layer, having a thickness ranging from 5 nm to 40 nm, and provided with a first opening penetrating through the anti-reflective layer;
a first electrode, wherein a part of the first electrode is in the first opening and is electrically connected to the emitter film layer;
a tunnel oxide layer on the second surface and having a thickness ranging from 1.3 nm to 1.6 nm, wherein the thickness difference measured by five points measurement thereon is less than 4%, and the tunnel oxide layer is made by an atomic layer deposition process;
a semiconductor film layer being the first type doped semiconductor, on the tunnel oxide layer, and having a thickness ranging from 100 nm to 150 nm; and
a second electrode on the semiconductor film layer and being electrically connected to the semiconductor film layer.

2. The tunnel oxide passivated contact solar cell according to claim 1, further comprising a first protective layer, wherein the first protective layer is on the anti-reflective layer and is provided with a through hole, the through hole is communicated with the first opening, and a part of the first electrode is in the first opening and the through hole and is electrically connected to the emitter film layer.

3. The tunnel oxide passivated contact solar cell according to claim 2, further comprising a second protective layer, wherein the second protective layer is on the semiconductor film layer and is provided with a second opening penetrating through the second protective layer, and a part of the second electrode is in the second opening and is electrically connected to the semiconductor film layer.

4. The tunnel oxide passivated contact solar cell according to claim 2, further comprising a second tunnel oxide layer between the emitter film layer and the first surface, wherein the second oxide layer has a thickness ranging from 1.3 nm to 1.6 nm, the thickness difference measured by five points measurement thereon is less than 4%, and the second tunnel oxide layer is made by an atomic layer deposition process.

5. The tunnel oxide passivated contact solar cell according to claim 4, further comprising a transparent conductive layer between the emitter film layer and the anti-reflective layer, wherein the thickness of the transparent conductive layer ranges from 40 nm to 80 nm.

6. The tunnel oxide passivated contact solar cell according to claim 5, wherein the first electrode in the first opening is in contact with the transparent conductive layer.

7. The tunnel oxide passivated contact solar cell according to claim 5, further comprising a second transparent conductive layer on the semiconductor film layer, wherein the thickness of the second transparent conductive layer ranges from 40 nm to 80 nm, and the second electrode is in contact with the second transparent conductive layer.

8. The tunnel oxide passivated contact solar cell according to claim 1, wherein the thickness of the semiconductor substrate ranges from 90 um to 160 um.

9. The tunnel oxide passivated contact solar cell according to claim 1, wherein the first type doped semiconductor is an N type doped semiconductor, and the second type doped semiconductor is a P type doped semiconductor.

10. The tunnel oxide passivated contact solar cell according to claim 1, wherein the first type doped semiconductor is a P type doped semiconductor, and the second type doped semiconductor is an N type doped semiconductor.
